(19) United States
(12) Patent Application Publication
(10) Pub. No.: US 2025/0361598 A1
(43) Pub. Date: Nov. 27, 2025

(54) SOLAR-CONTROL COATING WITH IMPROVED BENDABILITY

(71) Applicant: 3E NANO INC., Toronto (CA)

(72) Inventors: Jose NUNEZ-REGUEIRO, Ann Arbor, MI (US); Navid SOHEILNIA, Richmond Hill (CA); Paulo Cesar DE MOURA, Sao Jose dos Campos, Sao Paulo (BR); Nazir Pyarali KHERANI, Toronto (CA); Alexey KRASNOV, Canton, MI (US)

(21) Appl. No.: 19/227,915

(22) Filed: Jun. 4, 2025

(51) Int. Cl. C23C 14/34; C09D 183/04; C23C 14/06; C23C 14/20

(52) U.S. Cl. CPC C23C 14/34; C09D 183/04; C23C 14/0617; C23C 14/0641; C23C 14/0676; C23C 14/205

(57) ABSTRACT

The present disclosure provides a solar-control infrared-reflecting thin-film stack on a polymeric substrate. The stack comprises a chromium-free nickel nitride or nickel-oxi-nitride blocker layer which results in an improved bendability of the stack which makes it ideal for using on polymeric panes in architectural and automotive glazing wherein such panes sustain expansion, contraction, and bending caused by environmental conditions, such as fluctuating temperature and humidity.

### FIELD

The present disclosure relates to solar-control thin-film structures and, particularly, to solar-control structures deposited on polymeric or thin-glass substrates and having improved elasticity.

### BACKGROUND

In response to regulatory requirements for environmentally friendly architectural and automotive glazing, coated glass manufacturers have been increasingly focused on improving the energy efficiency of their products. Solar irradiation control by reflecting infrared (IR) light using a coating comprising at least one thin silver (Ag) functional layer [U.S. Pat. No. 10,233,532B2] has traditionally been one of the key means of achieving this goal. Thin Ag has the advantage over other metals in acting as an effective notch filter, i.e., being highly transparent in the visible range of the electromagnetic spectrum while reflecting a considerable portion of IR light. Besides, thin silver, unlike, e.g., gold, does not add coloration to the coating [https://doi.org/10.1016/j.vacuum.2022.111228] which is important for good aesthetics of architectural coated glazing. Panes with solar-control coatings are often integrated in insulated glass units (IGUs) which become glazing for commercial and residential architectural applications.

Some reports disclose functional silver layers alloyed with other metals, such as Cu, Al, Ni, etc., to improve their corrosion resistance [CN103802379A, https://doi.org/10.1016/j.solmat.2022.112033, U.S. Pat. No. 11,685,688B2].

Solar-control coatings are typically deposited on rigid glass substrates using sputter deposition [US20030180547A1] and often comprise more than one silver layer [https://doi.org/10.1016/j.optmat.2023.113807], each of which is sandwiched between two single or stacked dielectric layers. The dielectric layers are designed to add anti-reflection properties as well as to protect the silver layer from corrosion caused by the diffusion of environmental oxygen and moisture. Typical materials selection for dielectric layers includes titanium dioxide (TiO₂), aluminum doped zinc oxide (ZnAlOx), zinc stannate (ZnSnO₄), silicon dioxide (SiO₂) and silicon nitride (Si₃N₄). From the substrate side, Ag is typically in direct contact with a so-called ‘wetting’ dielectric layer, the primary role of which is to improve the proper crystallinity of the silver, thus enhancing its IR reflecting properties as well as increasing its transparency in the visible. From the top side, the silver is typically capped by a so-called ‘blocker’ layer. The purpose of the blocker is twofold: a) to protect the delicate silver from damaging bombardment by high-energy species during the sputter deposition of the top portion of the thin-film stack and b) to improve the corrosion resistance of the silver during the heat-treatment step as well as during its exposure to environmental oxygen and moisture once installed in a final product. Nickel-chromium-oxide (NiCrOx) is the standard choice for this purpose due to its high optical transparency and good durability.

A better corrosion resistance compared to NiCrOx was achieved by several research groups using nickel-chromium-nitride (NiCrNx), from about 0.1 nm to about 0.6 nm thick, in the applications other than solar-control coatings, e.g., related to highly reflective silver-based telescope mirrors (https://doi.org/10.1117/1.oe.57.4.045101; https://doi.org/10.1117/12.2628337; https://doi.org/10.1117/12.2628337). The reported thin-film structure was Glass/NiCrNx/Ag/NiCrNx/SiNx and did not include a post-deposition heat treatment step. U.S. Pat. No. 6,078,425A disclosed the use of AlN as a dielectric layer immediately above the NiCrNx in a silver-based telescope mirror. An important limitation of U.S. Pat. No. 6,078,425A, however, was that the substrate was disclosed to comprise an additional aluminum metal layer—an essential element of the mirror design.

The use of NiCrNx as a blocker layer over silver was also reported [EP1427679] for color matching between non-heat-treatable and heat-treatable solar-control products deposited on glass substrates. An example embodiment included the following thin-film stack: glass/Si₃N₄/NiCrNx/Ag/NiCrNx/Si₃N₄. Si₃N₄ can be optionally replaced with another nitride. EP1427679, however, did not disclose AlN. It should be appreciated that the exact stoichiometry of the NiCrNx layer is not precisely known due to its small thickness and high inhomogeneity. The ‘x’ in the formula, therefore, means that the stoichiometry in the resultant layers may vary.

CN103802379A disclosed the use of a NiCrNx blocker layer on top of a Ag—Cu—Al functional layer.

The use of a NiNx layer on top of pure silver layer was disclosed in [WO1999064900A1] for NiNx/Ag/NiNx mirrors. WO1999064900A1, however, did not disclose the use of NiNx on top of an alloyed silver layer.

The use of a NiCrNx blocker layer on top of a Ag layer alloyed with Cu, Al, or Ni was disclosed in [CN103802379A].

The more traditional NiCrOx blocker layer is typically deposited in an argon-oxygen gas mixture at a very low power level of NiCr sputtering cathode to minimize the damage to the silver by the energetic plasma particles as well as reduce the silver oxidation (since only low oxygen levels are required in this case to maintain NiCrOx stoichiometry at a lower sputtering power). A NiCrNx blocker, on the contrary, allows the use of a higher cathode power level. This can be explained by less damage caused by nitrogen species compared to oxygen as well as by the lack of oxidation of the silver functional layer in the nitrogen atmosphere. Since NiCrNx works as a superior blocker layer compared to NiCrOx, it offers yet another benefit, i.e., allowing the use of higher cathode power during sputter deposition of the layers immediately above it. This, in turn, translates to higher sputter deposition rates and, as a result, to higher production yields.

The flip side of using NiCrNx instead of NiCrOx blocker is somewhat lower visible transmittance. Another difference between NiCrNx and NiCrOx—often neglected in related prior art—is that NiCrOx crystallizes during the room-temperature deposition. It also remains crystalline after post-deposition heat treatment. This is not a concern when a solar-control stack is deposited on a rigid glass substrate. However, when deposited on a polymeric pane susceptible to expansion, contraction, or bending, NiCrOx is prone to cracking caused by its crystallinity and the presence of chromium, which makes the material more corrosion resistant but brittle. This, in turn, compromises its moisture blocking properties.

NiCrNx, on the other hand, remains amorphous—and, thus, more elastic and less brittle—during and after its deposition, even when heat treated. This quality is essential not only for improved elasticity of the entire coating but also for the cases requiring conformal blocker on the underlying functional wetting layers and on functional layers having columnar structures with rough morphology and/or on said layers deposited on a substrate purposefully textured for better adhesion. The presence of chromium in NiCrNx, however, adds stiffness [https://doi.org/10.1016/j.surfcoat.2005.02.091] and compromises optical transmittance [https://doi.org/10.1116/1.1405513].

It would be desirable to provide a solution for a more elastic blocker layer suitable for the application on polymeric or thin-glass substrates subjected to expansion/contraction and bending. There is particular interest in such a blocker layer with improved elasticity, namely, to be part of solar-control coatings having good corrosion resistance when deposited on an unprotected surface of an IGU.

### SUMMARY

The present disclosure provides a solar-control structure comprising:
a polymeric substrate with a thickness from about 3 mm to about 16 mm, and
a solar-control coating comprising:
a bottom dielectric layer located on a surface of the substrate and having a thickness from about 10 nm to about 50 nm;
an infrared reflecting functional layer located on the bottom dielectric layer, wherein a thickness of said first infrared reflecting functional layer ranges from about 1 to about 20 nm, the infrared reflecting functional layer being made of
   a layer of Ag alloy, or
   a pure Ag layer, or
   the layer of the Ag alloy on the pure Ag layer,
a blocker layer of nickel nitride (NiNx) or nickel-oxi-nitride (NiOxNx) located directly on top of the infrared reflecting functional layer with a thickness ranging from about 1 to about 4 nm, where x in NiNx ranges from about 0.01 to about 0.99 at. %, and wherein the x in NiOxNx ranges from about 0.01 to about 0.99 at. %, and when the layer of Ag alloy is present it is in direct contact with the blocker layer (250), and when the pure Ag layer is present alone absent the layer of Ag alloy the pure Ag layer is in direct contact with the blocker layer;
a top dielectric layer with a thickness ranging from about 5 nm to about 50 nm located on the blocker layer;
a protective layer on top of the top dielectric layer with a thickness ranging from about 10 nm to about 40 nm.

A wetting layer may be located between the bottom dielectric layer and the functional layer.

The top dielectric layer may be aluminum nitride.

The AlN-based layer may be hydrogenated AlN.

The AlN-based layer may be hydrogenated aluminum-oxi-nitride.

The functional layer or any portion thereof may be an alloy of silver, copper, and aluminum.

The functional layer or any of its portions may contain nitrogen in a concentration of at least 1000 ppm.

The surface of the polymeric substrate located below the bottom dielectric layer may be primed with a hard coating. This hard coating may be made of a siloxane. The siloxane may be any one of polydimethylsiloxane, cyclopentasiloxane, and cyclohexasiloxane.

The blocker layer of nickel nitride (NiNx) may exist in the form of a combination of various phases of NiN, Ni₃N, Ni₄N and Ni₈N.

The solar-control structure according to claim 1, wherein the silver alloy is silver alloyed with copper and aluminum.

The solar-control structure may include a matching layer of ZnAlNx located directly above the blocker layer and having a thickness in a range from about 5 nm to about 25 nm. This matching layer of ZnAlNx may have a thickness in a range from about 10 nm to about 15 nm.

The solar-control structure may have a matching layer of ZnAlOxNy located directly above the blocker layer and having a thickness in a range from about 5 nm to about 25 nm and wherein the ‘x’ and the ‘y’ in the formula range from about 0.01 to about 0.99. This matching layer of ZnAlOxNy may have a thickness in a range from about 10 nm to about 15 nm.

The thickness of the bottom layer may be in a range from about 20 nm to about 30 nm.

The solar thickness of the top dielectric layer is in a range from about 20 to about 40 nm.

The thickness of the protective layer may be in a range from about 20 to about 40 nm.

The infrared reflecting functional layer may be a layer of pure Ag alone.

The infrared reflecting functional layer may be a layer of Ag alloy alone.

The infrared reflecting functional layer may be a bilayer comprising a sublayer of the silver alloy on top of the layer of pure Ag, wherein a total thickness of the bilayer is in a range from about 10 to about 25 nm.

The silver alloy is silver alloyed with at least one metal, the at least one metal being any one or combination of copper, aluminum, nickel, platinum and palladium.

The silver alloy may be silver-copper, silver-aluminum, silver-copper-aluminum, silver-nickel, or silver-copper-nickel. The Ag alloy with-copper, or aluminum, or both may have a composition of Ag: 90-99%; Cu: 0-10%; Al: 0-5%, wherein 0% may only apply to either copper or aluminum. It will be understood that when the composition of Cu is 0, the composition of Al is not 0 and it is a Ag—Al alloy, and conversely when the composition of Al is 0, the composition of Cu is not 0 and it is a Ag-Cu alloy. When neither Cu and Al are not 0, it is a Ag—Cu—Al alloy.

### BRIEF DESCRIPTION

According to the present disclosure, nickel nitride (NiNx) or a nickel nitrate, such as Ni(NO₃)₂, is introduced instead of nickel-chromium-oxide (NiCrOx) or nickel-chromium nitride (NiCrNx) as a blocker layer of a solar-control thin-film structure immediately above at least one functional infrared (IR) reflective layer comprising silver (Ag) alloyed with at least copper (Cu) and aluminum (Al). The structure, for example, may be sputter deposited at room temperature (with no intentional heating of the substrate) and without post-deposition heat treatment on a polymeric or thin-glass substrate to mitigate the negative impact of elastic (reversible) deformation due to the substrate contraction, expansion, and/or bending.

Nickel nitride thin films sputter deposited at room temperature typically exist in the form of a combination of various phases, such as NiN, Ni₃N, Ni₄N, and Ni₈N, which collectively add to a predominantly amorphous nature of NiNx [https://doi.org/10.1016/j.jallcom.2020.156299].

This and the absence of chromium explains a superior elasticity of NiNx compared to NiCrOx and even NiCrNx layers—a welcomed factor for solar-control coatings on polymeric substrates, especially when one or more silver functional layers alloyed with other metals, such as Cu, Al, nickel (Ni), platinum (Pt), palladium (Pd), etc., already possessing corrosion-resistant properties, are used. For convenience, a combination of different nickel nitride phases is denoted in the present disclosure as NiNx, wherein ‘x’ varies depending on the processing conditions and may or may not be homogeneous throughout the layer thickness. For example, x′ may be between 3 and 8. Elasticity is defined as the ability of a layer to return to its original shape after being stretched, compressed, or bent. Besides, NiNx is better suited than NiCrOx or even NiCrNx for the use of the coating on textured surfaces of the alloyed silver layers. Texture can be caused by a columnar crystal structure of the wetting layer or a granulated structure of the alloyed functional layer caused, for example, by the formation of corrosion-resistant Ag—Cu—Al—N core-shell nanocrystallites, as disclosed in recently filed patent application of the inventors of the present disclosure [Ser. No. 63/571,002]. It relates to the formation of Cu and Al nitrides surrounding pure-Ag particles during the deposition, followed by the conversion of the nitrides to form protective oxide shell—the process adding texture to the layer.

Amorphous NiNx is also advantageous to NiCrOx in case of the coating deposition on intentionally textured substrates. Examples include cured hard primer coatings applied on polymeric and textured substrates or substrates micropatterned by one of the following methods: micromachining, embossing, laser scribing, chemical patterning, etc. In this case, amorphous chromium-free NiNx has a higher chance compared to crystalline to thus retain its protective blocking properties compared to more brittle NiCrOx, or NiCrNx. Besides, occasional cracks caused by tensile stress in a solar-control coating tend to propagate on smooth surfaces, while surface texturing arrests such propagation to a localized area. Adjusting the portion of the stack immediately adjacent to the functional layer by using NiNx instead of NiCrOx or NiCrNx, therefore, adds the additional benefit of limiting the ingress of environmental oxygen and moisture into the functional layer through such cracks.

In an embodiment, a NiNx blocker, from about 0.7 to about 4 nm thick, is sputter deposited between a silver-inclusive functional layer and an aluminum nitride (AlN) top dielectric. The use of AlN in its hydrogenated form as a robust dielectric for solar-control structures has been disclosed by the inventors of the present disclosure elsewhere (CA3061105A). AlN in its thin-film form is known as a good choice of an elastic dielectric for flexible devices, such as flexible surface acoustic wave sensors [https://doi.org/10.1002/admt.202300362], flexible piezoelectric sensors [https://doi.org/10.1002/adfm.200600098], and flexible micro-electromechanical systems [https://doi.org/10.3390/s17051080].

The inventors of the present disclosure discovered that NiNx, owing to its amorphous nature, advantageously forms a much more elastic multilayer layer—as compared to the crystalline NiCrOx or NiCrNx—when it is placed between a pure silver or a silver alloy layer and an AlN layer. An elastic thin-film NiNx/AlN structure is formed, therefore, in the immediate proximity of the functional layer, thus ensuring moisture blocking of the alloyed silver layer during and after the substrate deformation. The inventors also discovered that the NiNx layer does not crystallize over time even when exposed to environmental oxygen or moisture. On the contrary, crystalline oxide or nitride of nickel-chromium creates a weak point in the Ag/NiCrOx/AlN part of the stack which may result in cracking of the coating when subjected to elastic deformations on a polymeric or a flexible thin-glass substrate.

Besides, NiNx acts as a sink to neutralize any oxygen that permeates through the top portion of the stack before reaching the functional silver layer and causing its damage.

In an embodiment, a ZnAlNx layer may be introduced on top of the NiNx blocker layer instead of traditionally used ZnAlOx [US2024199479A1] or ZnAlOxNy [EP4457191A1]. An AlN layer may optionally be introduced on top of the ZnAlNx layer. The rationale behind the use of ZnAlNx is similar to that for NiNx.

In a second aspect of the disclosure, the introduction of the NiNx blocker advantageously adds to the prevention of corrosion of the silver-inclusive functional layer during the deposition. Corrosion has a detrimental effect on the optical performance of Ag, specifically resulting in a reduced Tvis and IR reflectance. The use of NiNx was found to allow higher sputtering cathode power levels compared to NiCrOx or NiCrNx before silver damage caused by energetic sputtering particles occurs. This in turn allows better process control of the so-called ‘working point’ on the hysteresis curve [https://doi.org/10.1063/1.5042084] during the deposition of the blocker layer which translates to a better repeatability of the sputtering process and higher production yields.

Since the presence of residual oxygen and/or moisture in sputtering chambers during the deposition of NiNx may result in the formation of a nickel-oxi-nitride (NiOxNy) blocker layer, such as nickel (ii) nitrate (Ni(NO₃)₂) or another nitrate with uncontrollable ‘x’ and ‘y’ in its chemical formula, an embodiment of the present disclosure discloses a NiOxNy layer with 0.95≤y<1 and, correspondingly, 0.05≤x<1.

In an embodiment, the NiNx or NiOxNy layer is from about 0.7 nm to about 4 nm thick.

In an embodiment, the silver functional layer is between around 5 nm to about 25 nm thick.

In an embodiment, the functional layer is made of an alloy of silver with copper and aluminum.

In an embodiment, the functional layer is made of an alloy of silver with copper and aluminum deposited in an argon-nitrogen atmosphere.

In an embodiment, the functional layer is a bilayer, one sublayer of which is pure siler and the other sublayer, adjacent to the blocker layer, is an alloy of silver with copper and aluminum.

In an embodiment, the AlN layer above the blocker is undoped aluminum nitride.

In an embodiment, the AlN layer is doped with hydrogen.

In an embodiment, a ZnAlNx or ZnAlOxNy layer is introduced immediately above the NiNx blocker layer, thus forming a part of the stack with the sequence Ag/NiNx/ZnAlNx or Ag/NiNx/ZnAlOxNy.

In an embodiment, an AlN layer is deposited immediately above the ZnAlNx or ZnAlOxNy layer.

In an embodiment, the ZnAlNx or ZnAlOxNy layer comprises between about 1 and about 5 wt. % of aluminum.

In an embodiment, the polymeric substrate may comprise polycarbonate (PC), polymethyl methacrylate (PMMA), polyethylene terephthalate (PET), etc. Its thickness may range from about 1 to about 6 mm.

In an embodiment, the polymeric pane may be primed with an appropriate hard coating, such as siloxane disposed, e.g., by a gravitational flow or “doctor blade” process, or a vacuum-process deposited hard coat.

A further understanding of the functional and advantageous aspects of the disclosure can be realized by reference to the following detailed description and drawings.

### BRIEF DESCRIPTION OF THE DRAWINGS

The present disclosure can be understood by considering the following drawings and the legends for the reference numerals presented further below:

FIG. 1 is a schematic representation of a prior art solar-control coating comprising a NiCrOx or NiCrNx blocker layer.

FIG. 2A is a schematic representation, according to the present disclosure, of a solar-control coating comprising a NiNx blocker layer above an alloyed silver functional layer.

FIG. 2B is a schematic representation, according to the present disclosure, of a solar-control coating comprising a NiNx blocker layer above a pure silver functional layer.

FIG. 2C is a schematic representation, according to the present disclosure, of a solar-control coating comprising a NiNx blocker layer above a functional bilayer comprising a pure silver bottom sublayer and a top alloyed silver sublayer. An additional ZnAlNx or ZnAlOxNy layer on top of the blocker layer is also added.

FIG. 2D is an experimental cross-sectional transmission electron micrograph of an example solar-control coating comprising a NiNx blocker above a silver layer alloyed with copper and aluminum.

The accompanying drawings, which are incorporated in and form a part of this description, illustrate various embodiments of the disclosure, and together with the description, illustrate the principles of the disclosure, and enable those skilled in the art to make and use the disclosure.

Definition of the Reference Numerals used in the Drawings

| | |
|---|---|
| 100, 200 | Substrate |
| 110, 210 | Solar-control coating |
| 120, 220 | Foundation layer |
| 130, 230 | Wetting layer |
| 140, 240 | Alloyed silver functional layer |
| 150, 250 | Blocker layer |
| 160, 260 | Top dielectric layer |
| 170, 270 | Protective layer |
| 280 | ZnAlNx or ZnAlOxNy layer |
| 290 | Pure silver layer |

### DETAILED DESCRIPTION

A detailed description is provided below to facilitate a thorough understanding of the disclosed embodiments and connections thereof. The description is not limited to any particular example included herein.

Various embodiments and aspects of the disclosure will be described with reference to the details discussed below. The following description and drawings are illustrative of the disclosure and are not to be construed as limiting the disclosure. Numerous specific details are described to provide a thorough understanding of various embodiments of the present disclosure. The Figures are not to scale. Further, in certain instances, well-known or conventional details are not described in order to provide a concise discussion of embodiments of the present disclosure.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure. Unless otherwise specified, the terms “about” and “approximately” mean plus or minus 25 percent or less.

It is to be understood that unless otherwise specified, any specified range or group is as a shorthand way of referring to each and every member of a range or group individually, as well as each and every possible sub-range or sub-group encompassed therein and similarly with respect to any sub-ranges or sub-groups therein. Unless otherwise specified, the present disclosure relates to and explicitly incorporates each and every specific member and combination of sub-ranges or sub-groups.

As used herein, the term “on the order of”, when used in conjunction with a quantity or parameter, refers to a range spanning approximately one tenth to ten times the stated quantity or parameter.

The following terminology is used to describe the subject of the disclosure. A glazing is an article comprising at least one layer of a transparent material which serves to provide for the transmission of light and/or to provide for viewing of the side opposite the viewer and which is mounted in an opening in a building, vehicle, wall or roof or other framing member or enclosure. An insulating glass unit (IGU) is a glazing comprising two or more transparent panes spaced apart with the help of a spacer.

A polymeric glass pane is a pane which, unlike a traditional glass pane, comprises a polymeric (or plastic) material, such as, but not limited to, polycarbonate (PC), polymethyl methacrylate (PMMA), polyethylene terephthalate (PET), etc. Its thickness may range from about 1 to about 6 mm.

In an embodiment, the NiNx or NiOxNy layer is from about 0.7 nm and 4 nm thick.

In an embodiment, the silver functional layer thickness is between around 5 nm and about 25 nm.

In an embodiment, the functional layer is made of an alloy of silver with copper and aluminum.

In an embodiment, the functional layer is made of an alloy of silver with copper and aluminum deposited in an argon-nitrogen atmosphere.

In an embodiment, the functional layer is a bilayer, the bottom sublayer of which is pure silver and the top sublayer is an alloy of silver with copper and aluminum.

In an embodiment, the layer immediately above the blocker is undoped aluminum nitride (AlN).

In an embodiment, the layer immediately above the blocker layer is AlN doped with hydrogen.

In an embodiment, a ZnAlNx or ZnAlOxNy layer is introduced immediately above the NiNx or NiOxNy blocker layer, thus forming a part of the stack with the sequence Ag/NiNx/ZnAlNx or Ag/NiNx/ZnAlOxNy.

In an embodiment, an AlN layer is deposited immediately above the ZnAlNx or ZnAlOxNy layer.

In an embodiment, the ZnAlNx or ZnAlOxNy layer comprises between about 1 and about 5 wt. % of aluminum.

In an embodiment, the polymeric substrate may comprise, but is not limited to, polycarbonate (PC), polymethyl methacrylate (PMMA), polyethylene terephthalate (PET), etc. Its thickness may range from about 1 to about 6 mm.

In an embodiment, the polymeric pane may be primed with an appropriate hard coating, such as, but not limited to, siloxane disposed, e.g., by a gravitational flow or “doctor blade” process.

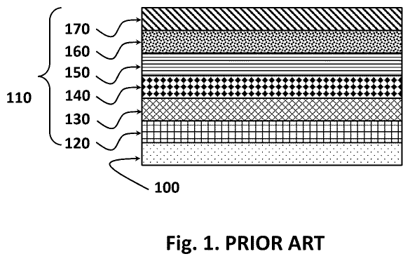

FIG. 1 is a schematic presentation of a solar-control coating of prior art. A substrate 100 can be a glass or a polymeric glass pane but may also be made of a combination of thereof, such as a hybrid composite comprised of two panes bonded together with a thermoplastic material, e.g., polyvinyl butyral (PVB), ethylene vinyl acetate (EVA), thermoplastic polyurethane (TPU), or ionomer resins.

On top of the substrate 100, a solar control coating 110 is deposited starting with a foundation dielectric layer 120. Examples of the foundation layer include titanium oxide (TiO₂), niobium oxide (Nb₂O₅), silicon oxide (SiO₂), silicon nitride (Si₃N₄), silicon oxynitride (SiOxNy), zinc stannate (ZnSnO₄), titanium silicon oxide (TiSiO₄), or zinc aluminum oxide (ZnAlOx). In some prior art designs, particularly those intended for post-deposition heat treatment, an additional barrier layer is deposited directly on glass substrate to prevent the unwanted migration of alkaline elements, such as sodium, from the substrate into the silver functional layer. Since the focus of the present disclosure is on polymeric glass substrates, the barrier layer is not shown in FIG. 1 representing prior art.

A wetting layer 130 is deposited on top of the foundation layer 120. Material choices for wetting layer 130 typically include ZnAlOx, AlN, and TiO₂. The role of this layer is to improve the crystal orientation, smoothness, and chemical adhesion of the functional layer 140 deposited on top of it. This is essential to enhance infrared reflective properties of the coating as well as to increase its visible light transmittance and ensure color neutrality. The functional layer 140 may comprise pure silver or an alloy of silver with other metals, such as copper (Cu), aluminum (Al), nickel (Ni), platinum (Pt), palladium (Pd), etc., or any combination thereof.

The purpose of the blocker layer 150 on top of the functional layer 140 is to provide an additional level of protection for the silver layer from corrosion, as well as to minimize the damage from energetic sputtering species during the deposition of the layer or layers immediately above the functional layer. It is made of nickel nitride or nickel oxynitride. The blocker later 150, according to prior art of FIG. 1 may comprise NiCrOx or NiCrNx on top of pure Ag or Ag—Cu—Al alloy or NiNx on top of pure Ag.

Immediately above the blocker layer 150, a top dielectric layer 160 is deposited. The role of this layer is to enable favorable optical properties of the stack, such as color neutrality. The physical phenomenon behind the optical functionality of this layer is optical interference. The transmittance, reflectance, and color of the coating can be tuned via the material selection and the layer thickness adjustment. The top dielectric layer 160 is made of AlN, ZnAlOx, ZnSnO₄, TiO₂, Nb₂O₅, TiSiO₄, TiZrO₄, or any other suitable dielectric.

The protection layer 170 above the top dielectric layer 160 is intended to provide additional mechanical protection to the deposited stack. It is made of any material from the following list: SiO₂, SiOxNy, ZrSiO₄, ZrO₂, TiO₂, or TiZrO₄.

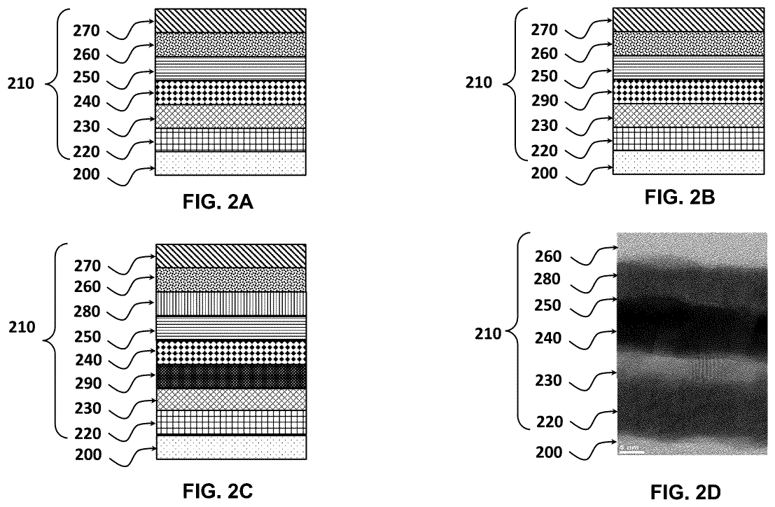

FIG. 2A is a schematic presentation of a solar-control coating according to the present disclosure. A substrate 200 can be a glass or a polymeric glass pane but may also be made of a combination of thereof, such as a hybrid composite comprised of two panes bonded together with thermoplastic material, e.g., PVB, EVA, TPU, or ionomer resins. On top of the substrate 200, a solar control coating 210 is deposited starting with a foundation dielectric layer 220. Examples of the foundation layer include TiO₂, Nb₂O₅, SiO₂, Si₃N₄, SiOxNy, ZnAlOx, and TiSiO₄.

The layer thickness ranges between about 5 and about 50 nm, preferably between about 10 and about 30 nm.

An optional wetting layer 230 is deposited on top of the foundation layer 220. Material choices for the wetting layer 230, which has thickness from about 5 to about 30 nm, preferably from about 7 to about 15 nm, include ZnAlOx, AlN, and TiO₂. The functional layer 240 comprises an alloy of silver with other metals, such as Cu, Al, Ni, Pt, Pd, Au, and Cr, or any combination thereof. The total thickness of the functional layer 240 ranges from about 5 to about 25 nm, preferably from about 10 to about 15 nm. The preferred alloy composition of the functional layer 240 is Ag—Cu—Al, and the atomic percentage concentration ranges are as follows: Ag: 90-99%; Cu: 0-10%; Al: 0-5%. The functional layer 240 may also comprise nitrogen.

The purpose of the blocker layer 250 on top of the functional layer 240 is to provide an additional level of protection for the silver layer from corrosion, as well as to minimize the damage from energetic sputtering species during the deposition of the layer or layers immediately above the functional layer. The thickness of the blocker layer 250 is from about 0.5 to about 5 nm, preferably between about 1 and about 3 nm. It is made of nickel nitride (NiNx). The ‘x’ in the NiNx formula may range from about 0.01 to about 0.99 at. %. The layer may comprise one or more nickel nitride phases, such as NiN, Ni₃N, Ni₄N, Ni₈N, etc. Since the presence of residual oxygen and/or moisture in sputtering chambers during the deposition of NiNx may result in the formation of a nickel-oxi-nitride (NiOxNy) blocker layer 250, such as nickel (ii) nitrate (Ni(NO₃)₂) or another nitrate NiOxNy with uncontrollable ‘x’ and ‘y’ in its chemical formula, an embodiment of the present disclosure discloses a NiOxNy layer with 0.95≤y<1 and, correspondingly, 0.05≤x<1.

Immediately above the blocker layer 250, a top dielectric layer 260 is deposited. The role of this layer is to enable favorable optical properties of the stack, such as color tuning. The top dielectric layer 260 is made of AlN, ZnAlOx, ZnSnOx, TiO₂, Nb₂O₅, ZrO₂, TiSiO₄, TiZrO₄, or any other suitable dielectric. The thickness of the top dielectric layer 260 ranges from about 10 to about 80 nm, preferably from about 30 and about 60 nm.

The protection layer 270 above the top dielectric layer 260 is intended to provide additional mechanical protection to the deposited stack. It is made of any material from the following list: SiO₂, SiOxNy (x ranges from 0 to 0.99; y ranges from 0.01 to 1), ZrSiO₄, ZrO₂, TiO₂, ZrTiO₄, and its thickness ranges from about 10 and about 60 nm, preferably from about 15 and about 30 nm.

FIG. 2B is a schematic presentation of a solar-control coating wherein the functional layer 290 is made of pure silver.

FIG. 2C is a schematic presentation of a solar-control coating according to the present disclosure, additionally comprising a matching layer 280 between the blocker layer 250 and the top dielectric layer 260. The purpose of the matching layer is to provide the optimal transition of mechanical and optical properties between the layers 250 and 260. The matching layer 280 may be made of ZnAlOx or zinc aluminum nitride (ZnAlNx). Its thickness ranges from about 5 to about 25 nm, preferably from about 10 to about 15 nm. The functional layer of FIG. 2C comprises two sublayers, the bottom layer 290 is comprised of pure silver and the top layer 240 is comprised of an alloy of silver with Cu and Al.

According to the present disclosure, the NiNx or NiOxNy blocker layer 250 is in direct contact with either a) alloyed Ag, shown in FIG. 2A; b) pure Ag, as shown in FIG. 2B or c) alloyed Ag sublayer, which sits on top of pure Ag in case of bilayer functional layer shown in FIG. 2C.

FIG. 2D is an experimental transmission electron microscopy (TEM) cross-sectional image of an example solar-control coating, wherein each individual layer of the stack is shown. The difference of solar-control stack 210 from the prior-art stack 110 (FIG. 1) is the material composition of blocker layer 250—a chromium-free NiNx or NiOxNy, which results in a more flexible stack 210 compared to layer stack 110 in FIG. 1. The absence of chromium which adds to the corrosion-resistant properties of the blocker layer 250 is compensated by using alloyed silver sublayer (such as Ag—Cu—Al) in the functional layer 240 with or without an additional pure silver sublayer 290.

All layers of the thin-film stack can be preferentially deposited using metal or ceramic sputtering targets. The targets can be planar, rotatable, or any combination thereof. Other apparatus and additions to the plasma process, such as collimators, electron-confining magnets, or high-power impulse magnetron sputtering, can also be used.

Examples of the embodiments are presented below. The disclosed examples are illustrative and should not be considered as restrictive.

### EXAMPLE 1

Example one is a solar-control coating deposited on a 3 mm thick PMMA substrate primed with a siloxane hard coating, the solar-control coating comprising, starting from the substrate, a 14 nm thick Nb₂O₅foundation layer, a 12 nm thick alloyed Ag—Cu—Al functional layer, a 1.5 nm NiNx blocker layer (x=0.5), a 25 nm thick AlN layer, and a 20 nm thick layer of Si₃N₄.

### EXAMPLE 2

Example two is similar to Example one except that the blocker layer is 1.5 nm thick nickel oxynitride (NiOxNy with x=0.05; y=0.95) layer.

### EXAMPLE 3

Example three is similar to Example one except that the functional layer is made of an Ag—Cu—Al—N alloy as a result of depositing Ag—Cu—Al in argon-nitrogen atmosphere.

### EXAMPLE 4

Example four is similar to Example one except that the functional layer is a bilayer, the bottom (closest to the foundation layer) sublayer of which is comprised of pure silver and the top sublayer is an Ag—Cu—Al alloy.

### EXAMPLE 5

Example five is similar to Example one except that the AlN layer is doped with hydrogen with a concentration of about 0.1 at. % of the hydrogen.

### EXAMPLE 6

Example six is similar to Example one except that a 10 nm thick ZnAlNx (x=0.3) layer is introduced between the blocker layer and the AlN layer.

### EXAMPLE 7

Example seven is similar to Example one except that a 10 nm thick ZnAlOxNy (x=0.05; y=0.25) layer is introduced between the blocker layer and the AlN layer.

List of References

| Publication | Priority | Publication | | |
|---|---|---|---|---|
| Number | Date | Date | Assignee | Title |
| U.S. Pat. No. 1,1685,688B2 | 2018 Oct. 22 | 2023 Jun. 27 | MIMSI | Glazing and method of its |
| | | | MATERIALS | production |
| | | | AB | |
| CN103802379A | 2014 Jan. 26 | 2015 Aug. 05 | CHANGJIANG | Temperable low- |
| | | | GLASS Co Ltd | emissivity coated glass |
| | | | TAIBO | containing silver alloy |
| U.S. Pat. No. 10,233,532B2 | 2017 Mar. 01 | 2019 Mar. 19 | Guardian | Coated article with low-E |
| | | | Industries | coating having reflecting |
| | | | Corp. | system with silver and |
| | | | | zinc based barrier layer(s) |
| U.S. Pat. No. 11,685,688B2 | 2019 Oct. 22 | 2023 Jun. 27 | MIMSI | Glazing and method of its |
| | | | Materials | production |
| U.S. Pat. No. 9,561,981B2 | 2014 Feb. 14 | 2017 Feb. 07 | AGC Glass | Glass panel comprising a |
| | | | Europe SA | solar control layer |
| US20030180547A1 | 2003 Feb. 11 | 2003 Sep. 25 | PPG Industries | Solar control coating |
| U.S. Pat. No. 5,737,885A | 1996 Mar. 29 | 1998 Apr. 14 | Eckhart Albert | Secondary interior window |
| | | | Stoyke | |
| CA3061105A | 2017 Apr. 17 | 2018 Oct. 25 | 3e Nano Inc | Energy control coatings, |
| | | | | structures, devices, and |
| | | | | methods of fabrication |
| | | | | thereof |
| U.S. Pat. No. 4,900,633A | 1987 Mar. 26 | 1990 Feb. 13 | PPG | High performance |
| | | | Industries, Inc. | multilayer coatings |
| U.S. Pat. No. 11,008,800B2 | 2018 May 29 | 2021 May 18 | Alpen High | Secondary window |
| | | | Performance | |
| | | | Products Inc | |
| US20240199479A1 | 2022 Jun. 29 | 2024 Jun. 20 | AGP eGlass | Improved solar coating |
| | | | | method of manufacture |
| | | | | and glass laminate |
| | | | | comprising such coating |

### NPL

1) R.C. Ross, Observations on humidity-induced degradation of Ag-based low-emissivity films, https://doi.org/10.1016/0165-1633(90)90040-8
2) Y. Hu., et al., Understanding the Preferred Crystal Orientation of Sputtered Silver in Ar/N2 Atmosphere: A Microstructure Investigation, https://doi.org/10.1155/2019/3079393
3) M. Zamani, et al., Optimization of heat treatment of Al—Cu—(Mg—Ag) cast alloys, https://doi.org/10.1007/s10973-019-08702-x
4) J. Wu, et al., Design and realization of neutral-tinted low-E film, https://doi.org/10.1016/j.vacuum.2022.111228
5) W. Shamsuddin, et al., Environmentally robust Ag—Cu based low-e coatings, https://doi.org/10.1016/j.solmat.2022.112033
6) A. Krasnov, et al., Optical considerations for automotive windshields with improved thermal performance, https://doi.org/10.1016/j.optmat.2023.113807
7) K. Folgner, et al., Variable composition in NiCrNx adhesion layers for protected silver mirrors and the effect on mirror durability, https://doi.org/10.1117/12.2628337
8) A. Lippitz, et al., XPS investigations of chromium nitride thin films, https://doi.org/10.1016/j.surfcoat.2005.02.091
9) S. Aouadi, et al., Spectroscopic ellipsometry measurements of chromium nitride coatings, https://doi.org/10.1116/1.1405513
10) L. Lamanna, Recent Progress in Polymeric Flexible Surface Acoustic Wave Devices: Materials, Processing, and Applications, https://doi.org/10.1002/admt.202300362
11) M. Akiyama, et al., Preparation of Oriented Aluminum Nitride Thin Films on Polyimide Films and Piezoelectric Response with High Thermal Stability and Flexibility, https://doi.org/10.1002/adfm.200600098
12) C. Abels, et al., Nitride-Based Materials for Flexible MEMS Tactile and Flow Sensors in Robotics, https://doi.org/10.3390/s17051080

What is claimed is:

1. A solar-control structure comprising:
a polymeric substrate with a thickness from about 3 mm to about 16 mm, and
a solar-control coating comprising:
a bottom dielectric layer located on a surface of the substrate and having a thickness from about 10 nm to about 50 nm;
an infrared reflecting functional layer located on the bottom dielectric layer, wherein a thickness of said first infrared reflecting functional layer ranges from about 1 to about 20 nm, the infrared reflecting functional layer being made of
a layer of Ag alloy, or
a pure Ag layer, or
the layer of the Ag alloy on the pure Ag layer,
a blocker layer of nickel nitride (NiNx) or nickel-oxi-nitride (NiOxNx) located directly on top of the infrared reflecting functional layer with a thickness ranging from about 1 to about 4 nm, where x in NiNx ranges from about 0.01 to about 0.99 at. %, and wherein the x in NiOxNx ranges from about 0.01 to about 0.99 at. %, and when the layer of Ag alloy is present it is in direct contact with the blocker layer (250), and when the pure Ag layer is present alone absent the layer of Ag alloy the pure Ag layer is in direct contact with the blocker layer;
a top dielectric layer with a thickness ranging from about 5 nm to about 50 nm located on the blocker layer; and
a protective layer on top of the top dielectric layer with a thickness ranging from about 10 nm to about 40 nm.

2. The solar-control structure according to claim 1, wherein a wetting layer is located between the bottom dielectric layer and the functional layer.

3. The solar-control structure according to claim 1, wherein the top dielectric layer is aluminum nitride.

4. The solar-control structure according to claim 1, wherein the AlN-based layer is hydrogenated AlN.

5. The solar-control structure according to claim 1, wherein the AlN-based layer is hydrogenated aluminum-oxi-nitride.

6. The solar-control structure according to claim 1, wherein the functional layer or any portion thereof is an alloy of silver, copper, and aluminum.

7. The solar-control structure according to claim 1, wherein the functional layer or any of its portions contains nitrogen in a concentration of at least 1000 ppm.

8. The solar-control structure according to claim 1, wherein the surface of the polymeric substrate located below the bottom dielectric layer is primed with a hard coating.

9. The solar-control structure according to claim 8, wherein the hard coating is made of a siloxane.

10. The solar-control structure according to claim 9, wherein the siloxane is any one of polydimethylsiloxane, cyclopentasiloxane, and cyclohexasiloxane.

11. The solar-control structure according to claim 1, wherein the blocker layer of nickel nitride (NiNx) exists in the form of a combination of various phases of NiN, Ni₃N, Ni₄N and Ni₈N.

12. The solar-control structure according to claim 1, wherein the silver alloy is silver alloyed with copper and aluminum.

13. The solar-control structure according to claim 1, wherein a matching layer of ZnAlNx is added directly above the blocker layer and having a thickness in a range from about 5 nm to about 25 nm.

14. The solar-control structure according to claim 13, wherein the matching layer of ZnAlNx has a thickness in a range from about 10 nm to about 15 nm.

15. The solar-control structure according to claim 1, wherein a matching layer of ZnAlOxNy is added directly above the blocker layer and having a thickness in a range from about 5 nm to about 25 nm and wherein the ‘x’ and the ‘y’ in the formula range from about 0.01 to about 0.99.

16. The solar-control structure according to claim 15, wherein the matching layer of ZnAlOxNy has a thickness in a range from about 10 nm to about 15 nm.

17. The solar-control structure according to claim 1, wherein the thickness of the bottom layer is in a range from about 20 nm to about 30 nm.

18. The solar-control structure according to claim 1, wherein the thickness of the top dielectric layer is in a range from about 20 to about 40 nm.

19. The solar-control structure according to claim 1, wherein the thickness of the protective layer is in a range from about 20 to about 40 nm.

20. The solar-control structure according to claim 1, wherein the infrared reflecting functional layer is a layer of pure Ag.

21. The solar-control structure according to claim 1, wherein the infrared reflecting functional layer is a layer of Ag alloy.

22. The solar-control structure according to claim 1, wherein the infrared reflecting functional layer is a bilayer comprising a sublayer of the silver alloy on top of the layer of pure Ag, wherein a total thickness of the bilayer is in a range from about 10 to about 25 nm.

23. The solar-control structure according to claim 22, wherein the silver alloy is silver alloyed with at least one metal, the at least one metal being any one or combination of copper, aluminum, nickel, platinum and palladium.

24. The solar-control structure according to claim 22, wherein the silver alloy is silver-copper, silver-aluminum, silver-copper-aluminum, silver-nickel, or silver-copper-nickel.

25. The solar-control structure according to claim 24, wherein the Ag alloy of silver-copper-aluminum has a composition of Ag: 90-99%; Cu: 0-10%; Al: 0-5%.
